(19) United States
(12) Patent Application Publication
(10) Pub. No.: US 2026/0076081 A1
(43) Pub. Date: Mar. 12, 2026

(54) DISPLAY APPARATUS, ELECTRONIC DEVICE, AND METHOD OF MANUFACTURING DISPLAY APPARATUS

(71) Applicant: Samsung Display Co., Ltd., Yongin-Si (KR)

(72) Inventors: Hyangyul Kim, Yongin-si (KR); Jaehong Kim, Yongin-si (KR); Changhan Lee, Yongin-si (KR); Jiwon Jung, Yongin-si (KR)

(21) Appl. No.: 19/217,204

(22) Filed: May 23, 2025

(30) Foreign Application Priority Data
Sep. 12, 2024 (KR) 10-2024-0125047

(51) Int. Cl. H10K 59/80; H10K 59/12

(52) U.S. Cl. CPC H10K 59/8792; H10K 59/1201

(57) ABSTRACT

Provided are a display apparatus and a method of manufacturing the display apparatus. The display apparatus has a display area and a non-display area, and includes a substrate in the display area and the non-display area, a display layer including a plurality of pixels disposed in the display area, an encapsulation member covering the display layer, a light-controlling layer disposed on the encapsulation member, and a polarizing film layer disposed on the light-controlling layer, wherein the light-controlling layer includes a plurality of light-blocking lines in a plan view, and each of the plurality of light-blocking lines includes a dual line.

### CROSS-REFERENCE TO RELATED APPLICATION

This application is based on and claims priority, under 35 U.S. C. § 119, to Korean Patent Application No. 10-2024-0125047 filed on Sep. 12, 2024 in the Korean Intellectual Property Office, the disclosure of which is incorporated by reference herein in its entirety.

### BACKGROUND

### 1. Field

One or more embodiments relate to an apparatus and a method, and more particularly, to a display apparatus and a method of manufacturing the display apparatus.

### 2. Description of the Related Art

Recently, electronic apparatuses are widely used. Electronic apparatuses are variously used as mobile electronic apparatuses and stationary electronic apparatuses. To support various functions, the electronic apparatus includes a display apparatus which may provide visual information such as images to users.

Recently, applications for display apparatuses has become increasingly diverse. In addition, as display apparatuses have become thinner and lighter, their range of use has expanded. As display apparatuses are being utilized in various fields, the demand for display apparatuses providing high-quality images has increased. For example, a display apparatus is disposed inside a vehicle to provide images to a user sitting on a driver's seat or a passenger seat.

The above-mentioned information is provided as background, and is not necessarily considered to be a known art open to the general public prior to the filing of the disclosure.

### SUMMARY

One or more embodiments include a display apparatus with improved display quality that may be disposed inside a vehicle, and a method of manufacturing the display apparatus.

Additional aspects will be set forth in part in the description which follows and, in part, will be apparent from the description, or may be learned by practice of the presented embodiments of the disclosure.

According to one or more embodiments, a display apparatus having a display area and a non-display area includes a substrate in the display area and the non-display area, a display layer including a plurality of pixels disposed in the display area, an encapsulation member covering the display layer, a light-controlling layer disposed on the encapsulation member, and a polarizing film layer disposed on the light-controlling layer, wherein the light-controlling layer includes a plurality of light-blocking lines in a plan view, and each of the plurality of light-blocking lines includes a dual line.

In an embodiment, each of the plurality of light-blocking lines may extend between the plurality of pixels.

In an embodiment, the plurality of pixels may be arranged in a first direction with space between neighboring pixels, and the plurality of light-blocking lines may extend in a direction that is orthogonal to the first direction.

In an embodiment, the plurality of light-blocking lines may be disposed spaced apart from each other in the first direction.

In an embodiment, a separation distance between the plurality of light-blocking lines in the first direction may be greater than a width of each of the pixels measured in the first direction.

In an embodiment, the dual line may include a pair of sub-lines, and a distance between the pair of sub-lines may be less than a distance between the plurality of light-blocking lines.

In an embodiment, the light-controlling layer may include a transmissive layer disposed on the encapsulation member and including a body portion extending away from the encapsulation member, a light-blocking coated layer covering the body portion to form the plurality of light-blocking lines, and an overcoat layer covering the transmissive layer.

In an embodiment, the transmissive layer may include a transparent material.

In an embodiment, the transmissive layer may be on the encapsulation member and in direct contact with the encapsulation member.

In an embodiment, the body portion may have a cross-section having a shape of a trapezoid having a short side that is farther from the encapsulation member than a long side, a first surface forming the short side and a second surface connecting an edge of the first surface to the long side.

In an embodiment, the light-blocking coated layer may cover the second surface but not the first surface to form the dual line.

In an embodiment, light emitted from the display layer may pass through the first surface.

In an embodiment, the body portion may be provided in plurality, and a distance between the plurality of body portions may be greater than a width of one of the pixels.

According to one or more embodiments, an electronic device includes a display apparatus that has a display area and a non-display area, and includes a substrate in the display area and the non-display area, a display layer including a plurality of pixels disposed in the display area, an encapsulation member covering the display layer, a light-controlling layer disposed on the encapsulation member, and a polarizing film layer disposed on the light-controlling layer, wherein the light-controlling layer includes a transmissive layer disposed on the encapsulation member and including body portions separated by a groove, and a light-blocking line disposed to fill the groove.

In an embodiment, the transmissive layer may include a transparent material.

In an embodiment, a cross-section of each of the body portions may have a trapezoidal shape.

In an embodiment, the transmissive layer may be in direct contact with the encapsulation member.

According to one or more embodiments, a method of manufacturing a display apparatus includes providing an encapsulation member, disposing a layer of resin on the encapsulation member, rolling a mold on the resin to imprint a pattern on the resin, the pattern including a plurality of body portions separated by grooves, and disposing a light-blocking material on the imprinted resin.

In an embodiment, the method may further include ashing the light-blocking material to leave the coated light-blocking material on a sidewall of the body portion, and removing the coated light-blocking material from a remaining portion of the body portion.

In an embodiment, the method may further include disposing an overcoat layer to cover the resin.

These and/or other aspects will become apparent and more readily appreciated from the following detailed description of the embodiments, the accompanying drawings, and claims.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic view of the exterior of a vehicle according to an embodiment;

FIGS. 2 and 3 are schematic views of the interior of a vehicle according to an embodiment;

FIG. 4 is a schematic plan view of a display apparatus according to an embodiment;

FIG. 5 is a schematic equivalent circuit diagram of a sub-pixel according to an embodiment;

FIGS. 6 and 7 are schematic cross-sectional views of the display apparatus of FIG. 4, taken along line VI-VI′ in FIG. 4;

FIG. 8 is a schematic cross-sectional view of a display apparatus according to an embodiment, taken along line VIII-VIII′ of FIG. 4;

FIG. 9 is a schematic plan view of a display apparatus according to an embodiment;

FIG. 10 is a schematic cross-sectional view of a display apparatus according to an embodiment;

FIGS. 11 to 16 are schematic views showing a method of manufacturing a display apparatus, according to an embodiment; and

FIG. 17 is a schematic cross-sectional view of a display apparatus according to an embodiment.

FIG. 18 is a schematic diagram of an electronic device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, wherein like reference numerals refer to like elements throughout and a repeated description thereof is omitted.

While terms such as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

It will be understood that when a layer, region, or element is referred to as being “connected” to another layer, region, or element, it may be “directly connected” to the other layer, region, or element or may be “indirectly connected” to the other layer, region, or element with another layer, region, or element located therebetween. In addition, it will be understood that when a layer, region, or element is referred to as being “electrically connected” to another layer, region, or element, it may be “directly electrically connected” to the other layer, region, or element or may be “indirectly electrically connected” to other layer, region, or element with other layer, region, or element interposed therebetween.

Sizes of elements in the drawings may be exaggerated or reduced for convenience of explanation. For example, the size and thickness of each element shown in the drawings are arbitrarily represented for convenience of description, and thus, the disclosure is not necessarily limited thereto.

In an embodiment below, “A and/or B” means A or B, or A and B. In addition, “at least one of A and B” means A or B, or A and B.

As used herein, when a wiring is referred to as “extending in a first direction ,” it includes the possibility of the wiring extending not only in a straight line but also in a zigzag or in a curve generally in the first direction.

In an embodiment below, when referring to a “plan view”, it means an object portion is viewed from above. In embodiments below, when referring to a “cross-sectional view”, it means a cross-section of an object portion cut vertically is viewed from a side. As used herein, when it is referred that a first element “overlaps” a second element, the first element is arranged above or below the second element.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

In the case where a certain embodiment may be implemented differently, a specific process order may be performed in the order different from the described order. For example, two processes successively described may be simultaneously performed or be performed in the reverse order.

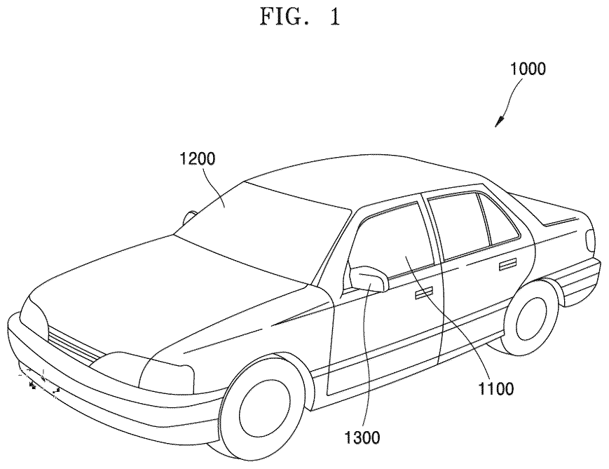

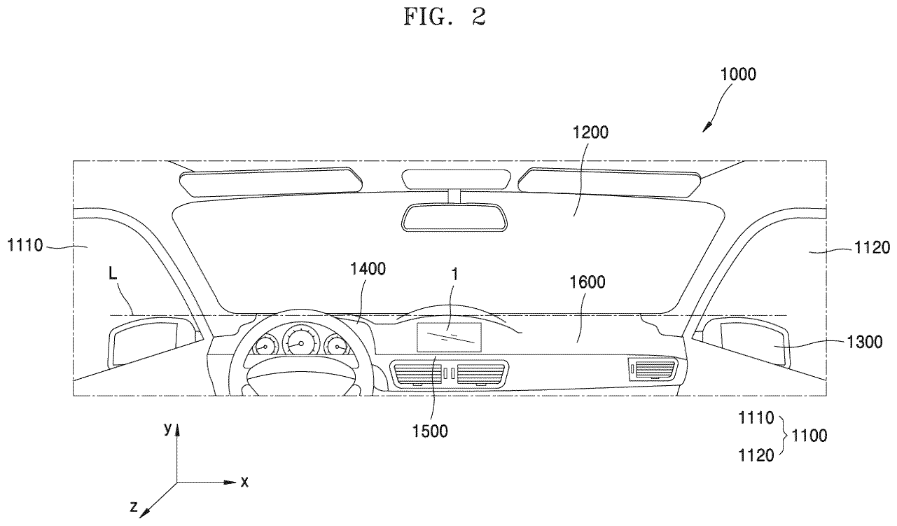

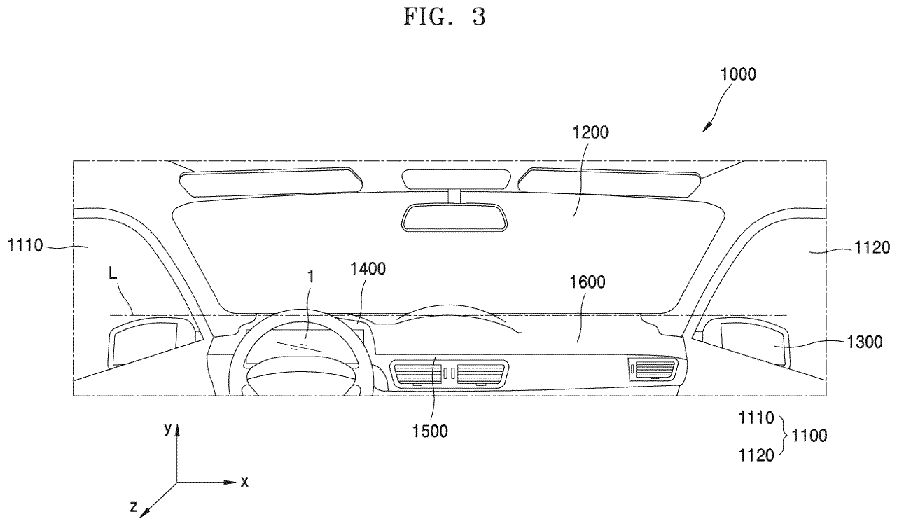

FIG. 1 is a schematic view of the exterior of a vehicle 1000 according to an embodiment. FIGS. 2 and 3 are schematic views of the interior of the vehicle 1000 according to an embodiment.

Referring to FIGS. 1, 2, and 3, the vehicle 1000 may denote various apparatuses that move or transport an object, a human being, an animal, or the like from one location to another. The vehicle 1000 may include a vehicle traveling on a road or track, a vessel moving over the sea or river, an airplane traveling in the sky, or a vehicle that is a combination of the above.

FIG. 1 depicts the vehicle 1000 that may travel on a road or track. The vehicle 1000 may move in a preset direction according to rotation of at least one wheel. For example, the vehicle 1000 may include a three-wheeled or four-wheeled vehicle, a construction machine, a two-wheeled vehicle, a motor apparatus, a bicycle, and a train running on a track.

The vehicle 1000 may include a body and a chassis, wherein the body has an interior and an exterior, and the chassis is the rest of parts other than the body. mechanical apparatuses required for driving are installed. The exterior of the body may include a front panel, a bonnet, a roof panel, a rear panel, a trunk, and a pillar provided in a boundary between doors. The chassis of the vehicle 1000 may include a power generating device, a power transmitting device, a driving device, a steering device, a braking device, a suspension device, a transmission device, a fuel device, front, rear, left, and right wheels, and the like.

The vehicle 1000 includes a side window 1100, a front window 1200, a side mirror 1300, a cluster 1400, a center fascia 1500, a passenger seat dashboard 1600, and a display apparatus 1. A “window,” as used herein, refers to a mostly transparent surface, such as a surface of glass.

The side window 1100 and the front window 1200 may be partitioned by a pillar disposed between the side window 1100 and the front window 1200.

The side window 1100 may be disposed on the lateral side of the vehicle 1000. In an embodiment, the side window 1100 may be attached to the door of the vehicle 1000. The side window 1100 may be provided in plurality and the plurality of side windows 1100 may face each other. In an embodiment, the side window 1100 may include a first side window 1110 and a second side window 1120. The first side window 1110 may be adjacent to the cluster 1400. The second side window 1120 may be adjacent to the passenger seat dashboard 1600.

The side windows 1100 may be apart from each other in a first direction (e.g., an x direction). For example, the first side window 1110 may be apart from the second side window 1120 in the x direction. In other words, a virtual connection line L connecting the side windows 1100 may extend in the first direction (e.g., the x direction).

The front window 1200 may be disposed on the front of the vehicle 1000. The front window 1200 may be disposed between the side windows 1100 facing each other.

The side mirror 1300 may provide a rear view of the vehicle 1000. The side mirror 1300 may be disposed on the exterior of the body. The side mirror 1300 may be provided in plurality. One of the plurality of side mirrors 1300 may be disposed on the outer side of the first side window 1110. Another of the plurality of side mirrors 1300 may be disposed on the outer side of the second side window 1120.

The cluster 1400 may be positioned in front of a steering wheel. A tachometer, a speedometer, a coolant thermometer, a fuel gauge turn indicator light, a high beam indicator light, a warning light, a seat belt warning light, an odometer, an automatic shift select level indicator light, a door open warning light, an engine oil warning light, and/or a low fuel warning light may be disposed in the cluster 1400.

The center fascia 1500 may include a control panel including a plurality of buttons for adjusting an audio device, an air conditioning device, and a heater of seats. The center fascia 1500 may be disposed on one side of the cluster 1400.

The passenger seat dashboard 1600 may be apart from the cluster 1400 with the center fascia 1500 therebetween. In an embodiment, the cluster 1400 may be disposed to correspond to a driver seat (not shown), and the passenger seat dashboard 1600 may be disposed to correspond to a passenger seat (not shown). In an embodiment, the cluster 1400 may be adjacent to the first side window 1110, and the passenger seat dashboard 1600 may be adjacent to the second side window 1120.

The display apparatus 1 may be disposed inside the vehicle 1000. The display apparatus 1 may be disposed between the side windows 1100. The display apparatus 1 may display images. In an embodiment, the display apparatus 1 may be disposed in one of the cluster 1400, the center fascia 1500, and the passenger seat dashboard 1600.

The display apparatus 1 may include liquid crystal displays, electrophoretic displays, organic light-emitting displays, inorganic light-emitting displays, field emission displays, surface-conduction electron-emitter displays, quantum dot displays, plasma displays, cathode ray displays, and the like. Hereinafter, though an organic light-emitting display apparatus is described as an example of the display apparatus 1 according to an embodiment, the various types of display apparatus described above may be used in embodiments.

Referring to FIG. 2, the display apparatus 1 may be disposed in the center fascia 1500. In an embodiment, the display apparatus 1 may display navigation information. In an embodiment, the display apparatus 1 may display information regarding audio, video, or vehicle settings.

Light emitted from the display apparatus 1 may propagate in a specific direction. For example, light emitted from the display apparatus 1 may propagate toward the driver seat (not shown). Light emitted from the display apparatus 1 may propagate toward a passenger seat (not shown). Light emitted from the display apparatus 1 may not propagate to the front window 1200. Alternatively, only a small fraction of the light emitted from the display apparatus 1 may propagate toward the front window 1200. In the case where light emitted from the display apparatus 1 propagates toward the front window 1200, the light emitted from the display apparatus 1 may be reflected by the front window 1200 toward the driver seat. The reflections of the images from the display apparatus 1 on the front window 1200 may distract the driver from focusing on the road in front of the vehicle 1000, thus interfering with safe driving. In the present embodiment, light emitted from the display apparatus 1 disposed in the center fascia 1500 may propagate in a specific direction away from the front window. Accordingly, it is possible to reduce the light that creates a reflection on the front window 1200.

Referring to FIG. 3, the display apparatus 1 may be disposed in the cluster 1400. In this case, the cluster 1400 may be configured to display driving information and the like by using the display apparatus 1. That is, the cluster 1400 may be implemented digitally. The digital cluster 1400 may display vehicle information and driving information by using images. For example, a needle of a tachometer and a gauge, and various warning light icons may be displayed by using digital signals.

Light emitted from the display apparatus 1 may propagate in a specified direction. For example, light emitted from the display apparatus 1 may propagate toward the driver seat (not shown). Light emitted from the display apparatus 1 may not propagate toward the front window 1200 and form a reflection. Alternatively, a small portion of the light emitted from the display apparatus 1 may propagate to the front window 1200. In the case where light emitted from the display apparatus 1 propagates toward the front window 1200, the light emitted from the display apparatus 1 may be reflected by the front window 1200 toward the driver seat. The reflection on the front window 1200 may distract the driver, creating a safety issue while driving. In the present embodiment, light emitted from the display apparatus 1 disposed in the cluster 1400 may propagate in a specified direction away from the front window 1200. Accordingly, light progressing toward the front window 1200 may be reduced.

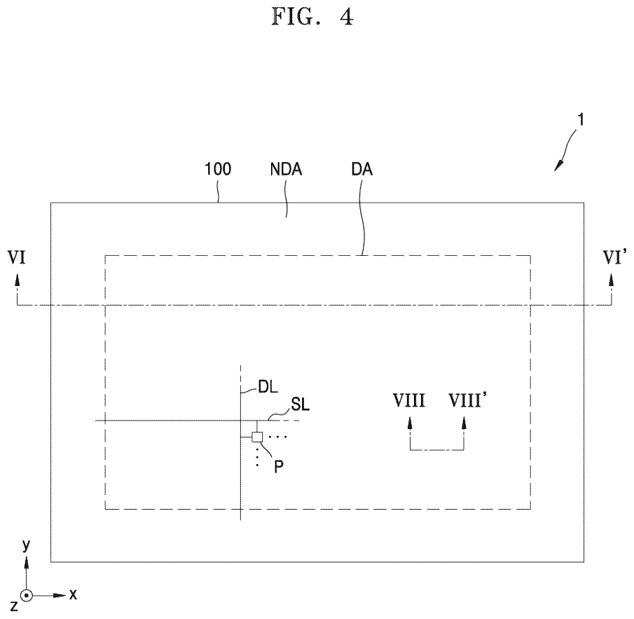

FIG. 4 is a schematic plan view of the display apparatus 1 according to an embodiment.

Referring to FIG. 4, the display apparatus 1 may include a display area DA and a non-display area NDA. The display apparatus 1 may include a substrate 100 and a plurality of layers on the substrate 100. The display area DA and the non-display area NDA may be defined in the substrate 100 and/or the layers on the substrate 100. For example, the display area DA and the non-display area NDA may be defined in the substrate 100. In other words, the substrate 100 may include the display area DA and the non-display area NDA.

A plurality of sub-pixels P may be disposed in the display area DA. The plurality of sub-pixels P may be configured to display images. The sub-pixel P may be connected to a scan line SL and a data line DL, wherein the scan line SL extends in the first direction (e.g., the x direction), and the data line DL extends in the second direction (e.g., the y direction).

The non-display area NDA may be disposed outside the display area DA. The non-display area NDA may surround at least a portion of the display area DA. In an embodiment, the non-display area NDA may surround the display area DA entirely. A scan driver (not shown) may be disposed in the non-display area NDA, wherein the scan driver provides scan signals to each sub-pixel P. A data driver (not shown) may be disposed in the non-display area NDA, wherein the data driver provides data signals to the sub-pixel P. The non-display area NDA may include a pad area (not shown). In an embodiment, a pad (not shown) may be disposed in the pad area. The pad may be exposed by not being covered by an insulating layer, and electrically connected to a printed circuit board or a driver integrated circuit (IC). Signals and/or voltages transferred from the printed circuit board or the driver IC through the pad may be transferred to the sub-pixel P disposed in the display area DA through a wiring (not shown) connected to the pad.

FIG. 2 is a schematic equivalent circuit diagram of a sub-pixel P according to an embodiment.

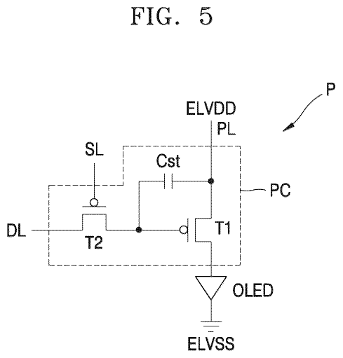

Referring to FIG. 5, the sub-pixel P may include a pixel circuit PC and an organic light-emitting diode OLED as a light-emitting element. The pixel circuit PC may include a driving thin-film transistor T1, a switching thin-film transistor T2, and a storage capacitor Cst. The sub-pixel P may emit, for example, red, green, or blue light, or emit red, green, blue, or white light by using the organic light-emitting diode OLED.

The switching transistor T2 is connected to the scan line SL and the data line DL, and configured to transfer a data voltage or a data signal to the driving transistor T1 according to a switching voltage or a switching signal input from the scan line SL, the data voltage or the data signal being input from the data line DL. The storage capacitor Cst may be connected to the switching transistor T2 and a driving voltage line PL and configured to store a voltage corresponding to a difference between a voltage transferred from the switching transistor T2 and a first power voltage ELVDD supplied to the driving voltage line PL.

The driving transistor T1 may be connected to the driving voltage line PL and the storage capacitor Cst and configured to control a driving current according to the voltage stored in the storage capacitor Cst, the driving current flowing from the driving voltage line PL to the organic light-emitting diode OLED. The organic light-emitting diode OLED may be configured to emit light having a preset brightness corresponding to the driving current. A common electrode (e.g., a cathode) of the organic light-emitting diode OLED may receive a second power voltage ELVSS.

Although it is shown in FIG. 5 that the pixel circuit PC includes two transistors and one storage capacitor, the pixel circuit PC may include three or more transistors.

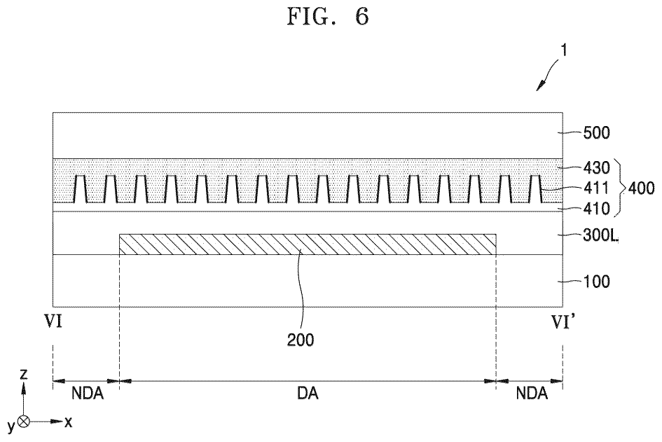

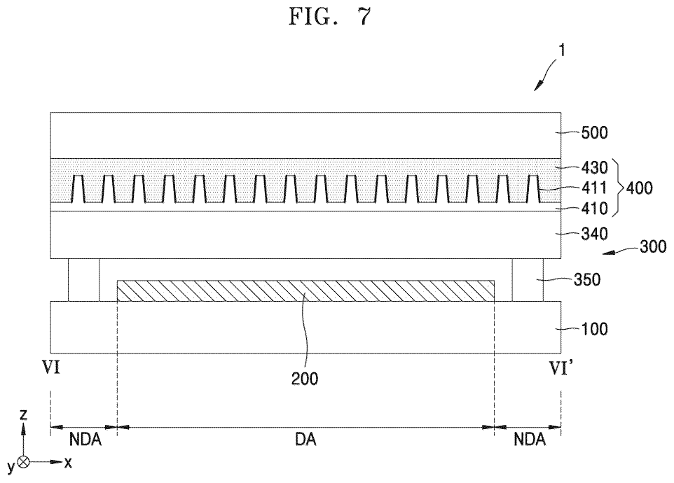

FIGS. 6 and 7 are schematic cross-sectional views of the display apparatus 1 of FIG. 4, taken along line VI-VI′.

Referring to FIGS. 6 and 7, the display apparatus 1 may include the substrate 100, a display layer 200, an encapsulation member 300, a light-controlling layer 400, and a polarizing film layer 500. The substrate 100 may include glass or a polymer resin such as polyethersulfone, polyarylate, polyetherimide, polyethylene naphthalate, polyethylene terephthalate, polyphenylene sulfide, polyimide, polycarbonate, cellulose tri acetate, cellulose acetate propionate, and the like. In an embodiment, the substrate 100 may have a multi-layered structure including a base layer and a barrier layer (not shown) each including the above polymer resin. The substrate 100 including the polymer resin is flexible, rollable, or bendable.

The display layer 200 may be disposed on the substrate 100. The display layer 200 may include a pixel circuit layer and a light-emitting element layer. The pixel circuit layer may include a pixel circuit. The pixel circuit may include a transistor and a storage capacitor. The light-emitting element layer may include a light-emitting element connected to the pixel circuit.

Referring to FIG. 6, the encapsulation member 300 may include an encapsulation layer 300L. The encapsulation layer 300L may include at least one inorganic encapsulation layer and at least one organic encapsulation layer. At least one inorganic encapsulation layer and at least one organic encapsulation layer may be stacked in turns. The at least one inorganic encapsulation layer may include at least one inorganic material among aluminum oxide (Al₂O₃), titanium oxide (TiO₂), tantalum oxide (Ta₂O₅), zinc oxide (ZnOₓ), silicon oxide (SiO₂), silicon nitride (SiNₓ), and silicon oxynitride (SiON). Zinc oxide (ZnOₓ) may include zinc oxide (ZnO) and/or zinc peroxide (ZnO₂).

The at least one organic encapsulation layer may include a polymer-based material. The polymer-based material may include an acryl-based resin, an epoxy-based resin, polyimide, and polyethylene. In an embodiment, the at least one organic encapsulation layer may include acrylate.

Referring to FIG. 7, the encapsulation member 300 may include an encapsulation substrate 340 and a sealing member 350. The encapsulation substrate 340 may be disposed on the display layer 200. The sealing member 350 may be disposed between the substrate 100 and the encapsulation substrate 340 in the non-display area NDA. The encapsulation substrate 340 may include a similar thickness to that of the substrate 100. For example, the thicknesses of the substrate 100 and the encapsulation substrate 340 may be about 0.3 mm. An inner space between the display layer 200 and the encapsulation substrate 340 may be sealed by the sealing member 350. The sealing member 350 may be sealant. In another embodiment, the sealing member 350 may include a material cured by a laser beam. For example, the sealing member 350 may include frit. Specifically, the sealing member 350 may include an organic sealant such as a urethane-based resin, an epoxy-based resin, an acryl-based resin, or an inorganic sealant. In an embodiment, the sealing member 350 may include silicone. As a urethane-based resin, for example, urethane acrylate or the like may be used. As acryl-based resin, for example, butyl acrylate, ethylhexyl acrylate, or the like may be used. The sealing member 350 may include a material cured by heat.

Referring to FIGS. 6 and 7, the light-controlling layer 400 may be disposed on the encapsulation member 300. The polarizing film layer 500 may be disposed on the light-controlling layer 400.

The light-controlling layer 400 may reduce reflectivity of light (e.g., external light) incident toward the display apparatus 1 from the outside, and simultaneously, control a propagation direction of light emitted from the display layer 200. For example, a component in a second direction (e.g., a y direction) of light emitted from the display layer 200 may be at least partially removed by the light-controlling layer 400.

In an embodiment, the light-controlling layer 400 may include a transmissive layer 410, a light-blocking coated layer 420, and an overcoat layer 430. These are described below in detail.

The polarizing film layer 500 may be disposed on the light-controlling layer 400. That is, the polarizing film layer 500 may be disposed further away from the display layer 200 than the light-controlling layer 400.

The polarizing film layer 500 may include a polarizing layer and a phase retarding layer. The phase retarding layer may include a film-type retarding layer or a liquid crystal coated-type retarding layer. The phase retarding layer may include a λ/2 phase retarder and/or a λ/4 phase retarder. The polarizing layer may include a film-type polarizing layer or a liquid crystal coated-type polarizing layer. The film-type polarizing layer may include a stretchable synthetic resin film, and the liquid crystal coated-type polarizing layer may include liquid crystals arranged in a preset arrangement. The polarizing film layer 500 may further include a protective layer disposed on and/or under the polarizing layer and the phase retarding layer. The polarizing film layer 500 may reduce reflectivity of light (e.g., external light) incident toward the display apparatus 1 from the outside and control a polarized state of light.

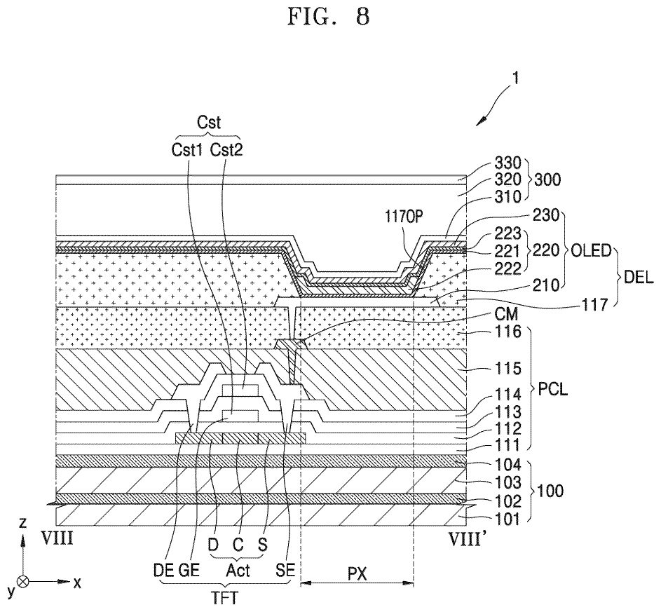

FIG. 8 is a schematic cross-sectional view of the display apparatus 1 according to an embodiment, taken along line VIII-VIII′ of FIG. 4. FIG. 8 mainly shows the display layer 200 and the encapsulation member 300 in particular, and layers on the encapsulation member 300 are omitted for convenience of description.

Referring to FIG. 8, the display apparatus 1 may include a stack structure of the substrate 100, a pixel circuit layer PCL, a display element layer DEL, and the encapsulation member 300.

The substrate 100 may have a multi-layered structure including a base layer that includes the polymer resin and an inorganic layer. For example, the substrate 100 may include the base layer including a polymer resin and a barrier layer including an inorganic insulating layer. For example, the substrate 100 may include a first base layer 101, a first barrier layer 102, a second base layer 103, and a second barrier layer 104 that are sequentially stacked. The first base layer 101 and the second base layer 103 may each include polyimide (PI), polyethersulfone (PES), polyarylate, polyetherimide (PEI), polyethylene naphthalate (PEN), polyethylene terephthalate (PET), polyphenylene sulfide (PPS), polycarbonate (PC), cellulose tri acetate (TAC), and/or cellulose acetate propionate (CAP). The first barrier layer 102 and the second barrier layer 104 may each include an inorganic insulating material such as silicon oxide, silicon oxynitride, and/or silicon nitride. The substrate 100 may be flexible.

The pixel circuit layer PCL is disposed on the substrate 100. FIG. 8 shows that the pixel circuit layer PCL includes a thin-film transistor TFT, a buffer layer 111, a first gate insulating layer 112, a second gate insulating layer 113, an interlayer insulating layer 114, a first planarization insulating layer 115, and a second planarization insulating layer 116 under and/or on elements of the thin-film transistor TFT.

The buffer layer 111 may reduce or block foreign materials, moisture, or external air penetrating from below the substrate 100 and may provide a flat surface on the substrate 100. The buffer layer 111 may include an inorganic insulating material such as silicon nitride, silicon oxynitride, and silicon oxide, and include a single-layered structure or a multi-layered structure including the above materials.

The thin-film transistor TFT on the buffer layer 111 may include a semiconductor layer Act, and the semiconductor layer Act may include polycrystalline silicon. Alternatively, the semiconductor layer Act may include amorphous silicon, an oxide semiconductor, or an organic semiconductor. The semiconductor layer Act may include a channel region C, a drain region D, and a source region S respectively disposed on two opposite sides of the channel region C. A gate electrode GE may overlap the channel region C.

The gate electrode GE may include a low-resistance metal material. The gate electrode GE may include a conductive material including molybdenum (Mo), aluminum (Al), copper (Cu), and titanium (Ti) and have a single-layered structure or a multi-layered structure including the above materials.

The first gate insulating layer 112 between the semiconductor layer Act and the gate electrode GE may include an inorganic insulating material including silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}). Zinc oxide (ZnO_{X}) may be zinc oxide (ZnO) and/or zinc peroxide (ZnO₂).

The second gate insulating layer 113 may cover the gate electrode GE. Similar to the first gate insulating layer 112, the second gate insulating layer 113 may include an inorganic insulating material including silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}). Zinc oxide (ZnOx) may be zinc oxide (ZnO) and/or zinc peroxide (ZnO2).

An upper electrode Cst2 of the storage capacitor Cst may be disposed on the second gate insulating layer 113. The upper electrode Cst2 may overlap the gate electrode GE therebelow. In this case, the gate electrode GE and the upper electrode Cst2 overlapping each other with the second gate insulating layer 113 therebetween may constitute the storage capacitor Cst. That is, the gate electrode GE may serve as a lower electrode Cst1 of the storage capacitor Cst.

As described above, the storage capacitor Cst may overlap the thin-film transistor TFT. In an embodiment, the storage capacitor Cst may be formed not to overlap the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu), and include a single layer or a multi-layer including the above materials.

The interlayer insulating layer 114 may cover the upper electrode Cst2. The interlayer insulating layer 114 may include silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}). Zinc oxide (ZnO_{X}) may be zinc oxide (ZnO) and/or zinc peroxide (ZnO₂). The interlayer insulating layer 114 may include a single layer or a multi-layer including the inorganic insulating material.

A drain electrode DE and a source electrode SE may each be disposed on the interlayer insulating layer 114. The drain electrode DE and the source electrode SE may be respectively connected to the drain region D and the source region S through contact holes of insulating layers therebelow. The drain electrode DE and the source electrode SE may each include a material having high conductivity. The drain electrode DE and the source electrode SE may each include a conductive material including molybdenum (Mo), aluminum (Al), copper (Cu), and titanium (Ti) and include a single layer or a multi-layer including the above materials. In an embodiment, the drain electrode DE and the source electrode SE may each have a multi-layered structure of Ti/Al/Ti.

The first planarization insulating layer 115 may cover the drain electrode DE and the source electrode SE. The first planarization insulating layer 115 may include an organic insulating material including a general-purpose polymer such as polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof.

The second planarization insulating layer 116 may be disposed on the first planarization insulating layer 115. The second planarization insulating layer 116 may include the same material as a material of the first planarization insulating layer 115 and may include an organic insulating material including a general-purpose polymer such as polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof.

The display element layer DEL may be disposed on the pixel circuit layer PCL having the above structure. The display element layer DEL may include an organic light-emitting diode OLED as a display element (that is, a light-emitting element). The organic light-emitting diode OLED may have a stack structure of a pixel electrode 210, an intermediate layer 220, and a common electrode 230. The organic light-emitting diode OLED may emit, for example, red, green, or blue light, or emit red, green, blue, or white light. The organic light-emitting diode OLED may be configured to emit light through an emission area. The emission area may be defined as a pixel PX.

The pixel electrode 210 of the organic light-emitting diode OLED may be electrically connected to the thin-film transistor TFT through contact holes formed in the second planarization insulating layer 116 and the first planarization insulating layer 115, and a contact metal CM disposed on the first planarization insulating layer 115.

The pixel electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In another embodiment, the pixel electrode 210 may further include a layer on/under the reflective layer, the layer including ITO, IZO, ZnO, or In₂O₃.

A pixel-defining layer 117 may be disposed on the pixel electrode 210, the pixel-defining layer 117 including an opening 117OP exposing a central portion of the pixel electrode 210. The pixel-defining layer 117 may include an organic insulating material and/or an inorganic insulating material. The opening 117OP may define the emission area of light emitted from the organic light-emitting diode OLED. For example, the size/width of the opening 117OP may correspond to the size/width of the emission area. Accordingly, the size and/or width of the pixel PX may depend on the size and/or width of the opening 117OP of the pixel-defining layer 117.

The intermediate layer 220 may include an emission layer 222 formed to correspond to the pixel electrode 210. The emission layer 222 may include a polymer organic material or a low-molecular weight organic material emitting light having a preset color. Alternatively, the emission layer 222 may include an inorganic emission material or quantum dots.

In an embodiment, the intermediate layer 220 may include a first functional layer 221 and a second functional layer 223 respectively disposed under and on the emission layer 222. The first functional layer 221 may include, for example, a hole transport layer (HTL), or include an HTL and a hole injection layer (HIL). The second functional layer 223 is an element disposed on the emission layer 222 and may include an electron transport layer (ETL) and/or an electron injection layer (EIL). Like the common electrode 230 described below, the first functional layer 221 and/or the second functional layer 223 may be common layers covering the substrate 100 entirely.

The common electrode 230 may be disposed on the pixel electrode 210 and may overlap the pixel electrode 210. The common electrode 230 may include a conductive material having a low work function. For example, the common electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), or an alloy thereof. Alternatively, the common electrode 230 may further include a layer on the (semi) transparent layer, the layer including ITO, IZO, ZnO, or In₂O₃. The common electrode 230 may be formed as one body to cover the substrate 100 entirely.

The encapsulation member 300 may be disposed on the display element layer DEL and may cover the display element layer DEL. In an embodiment, the encapsulation member 300 may include at least one inorganic encapsulation layer and at least one organic encapsulation layer. In the embodiment shown in FIG. 8, the encapsulation member 300 includes a first inorganic encapsulation layer 310, an organic encapsulation layer 320, and a second inorganic encapsulation layer 330 that are sequentially stacked. However, as described above, in another embodiment, it will be understood that the encapsulation member 300 may include the encapsulation substrate 340 (see FIG. 7) and the sealing member 350 (see FIG. 7). Hereinafter, for convenience of description, the description will focus on a case where the encapsulation member 300 includes at least one inorganic encapsulation layer and at least one organic encapsulation layer.

The first inorganic encapsulation layer 310 and the second inorganic encapsulation layer 330 may include at least one inorganic material from among aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include an acryl-based resin, an epoxy-based resin, polyimide, and polyethylene. In an embodiment, the organic encapsulation layer 320 may include acrylate. The organic encapsulation layer 320 may be formed by curing a monomer or coating a polymer. The organic encapsulation layer 320 may be transparent.

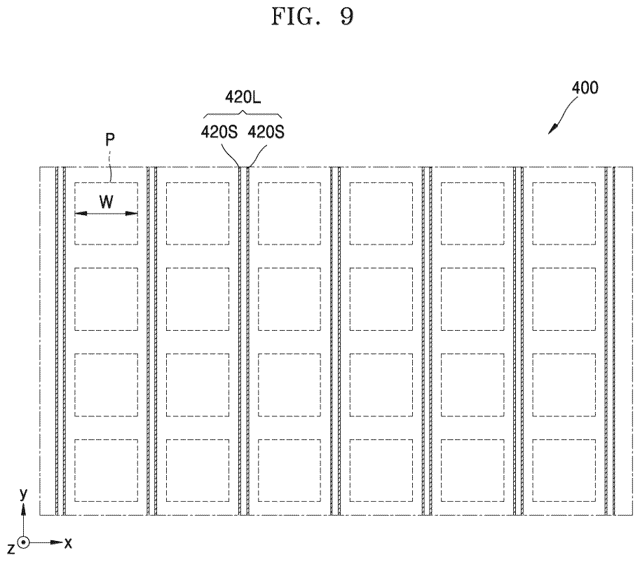

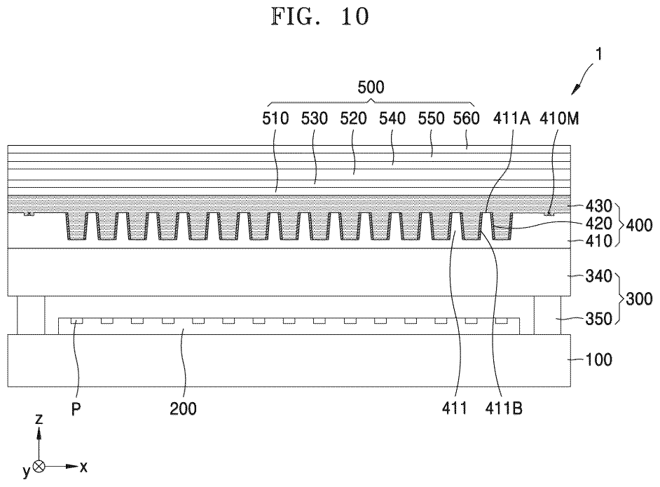

FIG. 9 is a schematic plan view of the display apparatus 1 according to an embodiment. Particularly, FIG. 9 mainly shows the light-controlling layer 400. FIG. 10 is a schematic cross-sectional view of the display apparatus 1 according to an embodiment. FIG. 10 is a cross-section of FIG. 9.

Referring to FIGS. 9 and 10, the display layer 200 including a plurality of pixels may be disposed on the substrate 100. In an embodiment, the plurality of pixels may be disposed apart from each other in the first direction (the x direction).

The encapsulation member 300 may be disposed on the display layer 200 to cover the display layer 200. In an embodiment, the encapsulation member 300 may include the encapsulation substrate 340 and the sealing member 350.

The light-controlling layer 400 may be disposed on the encapsulation member 300. In an embodiment, the light-controlling layer 400 may include the transmissive layer 410, the light-blocking coated layer 420, and the overcoat layer 430.

The transmissive layer 410 may be disposed on the encapsulation substrate 340, and in an embodiment, the transmissive layer 410 may be disposed to be in direct contact with the encapsulation substrate 340. For example, the transmissive layer 410 may be in direct contact with the encapsulation substrate 340. The transmissive layer 410 may include a transparent material. The transmissive layer 410 may include resin having a high light transmittance. For example, the transmissive layer 410 may include a cellulose resin, a polyolefin resin, a polyester resin, polystyrene, polyurethane, polyvinyl chloride, an acryl-based resin, and the like.

In an embodiment, the transmissive layer 410 may include a body portion 411 protruding toward the polarizing film layer 500 in the +z direction. The transmissive layer 410 may include a transparent material, and accordingly, it will be understood that the body portion 411 may also include a transparent material.

In an embodiment, the body portion 411 may be provided in plurality, and the plurality of body portions 411 may be disposed apart from each other in the first direction (x direction). In addition, each of the plurality of body portions 411 may extend in the second direction (y direction). In an embodiment, a distance (e.g., interval in the first direction) between the plurality of body portions 411 may be greater than the width W (measured in the first direction) of a pixel. In addition, the body portion 411 may be disposed between a plurality of pixels apart from each other in plan view (see FIG. 9) in the first direction and may extend in the second direction.

A cross-section of the body portion 411 viewed from the second direction (y direction) may be provided in the shape of a trapezoid in an embodiment. For example, the cross-section of the body portion 411 may be a trapezoid wherein the longer side is closer to the encapsulation substrate 340 than the shorter side. As used herein, a “trapezoid” refers to a parallelogram where two parallel sides have different lengths. Accordingly, the body portion 411 may include a first surface 411A and second surfaces 411B, wherein the first surface 411A is an upper surface and the second surface is a sidewall connected to an edge of the first surface 411A. The second surfaces 411B is depicted as being on two opposite sides of the first surface 411A in the first direction. In an embodiment, the first surface 411A may be a flat surface, and the second surface 411B may be a surface that is slanted with respect to the first surface 411A and extends from the edge of the first surface 411A toward the interface between the transmissive layer 410 and the encapsulation member 300.

In addition, in an embodiment, the transmissive layer 410 may further include an alignment mark 410M in the circumference thereof. This may facilitate alignment when disposing the encapsulation substrate 340 and the light-controlling layer 400 formed on the encapsulation substrate 340 on the substrate 100 and the display layer 200 disposed on the substrate 100.

The light-blocking coated layer 420 may be disposed to cover the transmissive layer 410, specifically, the body portion 411. In an embodiment, the light-blocking coated layer 420 may be disposed to cover the second surface 411B and not to cover the first surface 411A of the body portion 411. That is, the light-blocking coated layer 420 may be disposed to cover the sloped surface of the body portion 411. Accordingly, the light-blocking coated layer 420 may form a light-blocking line 420L shown in FIG. 9.

The light-blocking coated layer 420 may include a light-blocking material. For example, the light-blocking coated layer 420 may include black dye. The light-blocking coated layer 420 may include black ink and be formed by irradiating with ultraviolet ray. A path of light emitted from the display layer 200, for example, the pixels may be controlled according to the arrangement of the light-blocking coated layer 420.

The light-blocking coated layer 420 may be formed into the light-blocking line 420L. The light-blocking lines 420L may be apart from each other and be provided in plurality, and each of the plurality of light-blocking lines 420L may extend in the second direction (y direction) crossing the first direction. In an embodiment, an interval (e.g., interval in the first direction) between the plurality of light-blocking lines 420L may be greater than the width (e.g., measured in the first direction) of a pixel. In addition, the light-blocking lines 420L may be disposed between a plurality of pixels apart from each other in the first direction and may extend in the second direction. In other words, the plurality of light-blocking lines 420L may not overlap the plurality of pixels, and the plurality of light-blocking lines 420L may be apart from each other in the same direction as an arrangement direction of the plurality of pixels.

In an embodiment, the light-blocking line 420L may be provided as a dual line. In other words, the light-blocking line 420L may include a pair of parallel sub-lines 420S. As described above, because the light-blocking coated layer 420 is disposed on the sloped second surface 411B of the body portion 411 of the transmissive layer 410, the pair of parallel sub-lines 420S may be formed. In an embodiment, an interval between the pair of sub-lines 420S may be less than an interval between the plurality of light-blocking lines 420L.

Accordingly, light from the display layer 200 may pass between the pair of sub-lines 420S. In other words, light from the display layer 200 may transmit through the first surface 411A of the body portion 411 but not the second surface 411B. As described above, because light may be transmitted through the first surface 411A of the body portion 411 or between a pair of sub-lines 420S, a light transmittance may be further improved.

The overcoat layer 430 may be disposed to cover the transmissive layer 410 and the light-blocking coated layer 420. That is, the overcoat layer 430 may be disposed to fill a space between the plurality of body portions 411, and the overcoat layer 430 may planarize the upper surface of the light-controlling layer 400.

In an embodiment, the overcoat layer 430 may include a transparent material. The overcoat layer 430 may include resin having high light transmittance. For example, the overcoat layer 430 may include a cellulose resin, a polyolefin resin, a polyester resin, polystyrene, polyurethane, polyvinyl chloride, an acryl-based resin, and the like.

The polarizing film layer 500 may be disposed on the overcoat layer 430. In an embodiment, the polarizing film layer 500 may be disposed to be in direct contact with the light-controlling layer 400, for example, the overcoat layer 430. In an embodiment, the polarizing film layer 500 may include a first protective layer 510, a phase retarding layer 530, a polarizing layer 520, a second protective layer 540, and a hard coated layer 550.

The polarizing layer 520 polarizes light incident from a light source (not shown) into light in the same direction as a polarization axis. In an embodiment, the polarizing layer 520 may include a polarizer or/and a dichroic dye in a polyvinyl alcohol (PVA) film. Dichroic dye may be an iodine molecule or/and a dye molecule.

In an embodiment, the polarizing layer 520 may be formed by stretching a polyvinyl alcohol film in one direction and immersing it in a solution of iodine or/and a dichroic dye. In this case, iodine molecules and/or dichroic dye molecules are arranged parallel in a stretching direction. Because iodine molecules and dye molecules exhibit dichroism, they absorb light that vibrates in the stretching direction and transmit light that vibrates in a direction perpendicular to it.

The phase retarding layer (PRL) 530 may be disposed on one side of the polarizing layer 520 and may delay the phase of light reflected by a metal layer and the like inside a display panel. For example, the phase retarding layer 530 may circularly polarize reflected light by delaying its phase by λ/4. Accordingly, reflectivity of light may be reduced. In an embodiment, the phase retarding layer 530 may have a wavelength dependency, with a phase delay value decreasing toward shorter wavelengths. As shown in the drawing, the phase retarding layer 530 may be disposed under the polarizing layer 520.

The first protective layer 510 and the second protective layer 540 may serve as protective layers that support the polarizing layer 520 and the phase retarding layer 530 and supplement mechanical strength of the polarizing layer 520 and the phase retarding layer 530. The first protective layer 510 may be disposed under the phase retarding layer 530. The second protective layer 540 may be disposed on the polarizing layer 520. Alternatively, the second protective layer 540 may be disposed between the polarizing layer 520 and the phase retarding layer 530. Various modifications may be made.

The first protective layer 510 and the second protective layer 540 may include triacetyl cellulose (TAC), cyclo olefin polymer, or polymethyl methacrylate (PMMA).

The hard coated layer 550 may be an element for protecting elements of the polarizing film layer 500 from external impacts. The hard coated layer 550 may have a scratch-resistant function and have a strength of about 3 H to about 9 H. Because the hard coated layer 550 is disposed over the light-controlling layer 400, not only the polarizing film layer 500 but also the light-controlling layer 400 may be protected by the hard coated layer 550.

In an embodiment, a protective film 560 may be selectively disposed on the hard coated layer 550. The protective film 560 is a temporary film for protecting the polarizing film layer 500 and may be removed afterward.

According to embodiments, the light-controlling layer 400 may be on the encapsulation substrate 340 and in direct contact with the encapsulation substrate 340. Accordingly, an adhesive layer for adhering the light-controlling layer 400 to the encapsulation substrate 340 may be omitted, and the manufacturing process may be simplified.

In addition, the light-controlling layer 400 may be disposed on the encapsulation substrate 340 and disposed under the polarizing film layer 500. Accordingly, a distance from the display layer 200 may be reduced compared to a case where the light-controlling layer 400 is disposed on the polarizing film layer 500.

Generally, to form the light-controlling layer 400 controlling a light path, the transmissive layer 410 and the light-blocking coated layer 420 may be formed on a base film including polycarbonate or polyethylene terephthalate (PET). Then, the base film may be attached on the polarizing film layer 500 using a light-transparent adhesive layer.

In this case, due to the characteristics of the base film having double refraction, when the base film is disposed on the display layer 200, a double image (ghost image) may form. As a distance between the display layer 200 and the light-controlling layer 400 increases, the size of the double image may become larger and highly visible.

In the present embodiment, the base film and the light-transparent adhesive layer are not used, and in addition, the light-controlling layer 400 may be disposed under the polarizing film layer 500, and accordingly, disposed more adjacent to the display layer 200. Accordingly, transmittance of light emitted from the display layer 200 may be improved. In addition, an issue of a double image that may occur due to the distance from the display layer 200 may be prevented.

In addition, because the light-blocking lines 420L do not overlap the pixels and are disposed between the pixels, a moire phenomenon may be prevented. The light-blocking lines 420L may be apart from each other in the same direction as the arrangement direction of the pixels and disposed in direction orthogonal to the arrangement direction, which may symmetrically implement the brightness of the display apparatus 1 compared to a case where the light-blocking lines 420L are disposed to be sloped in the arrangement direction of the pixels.

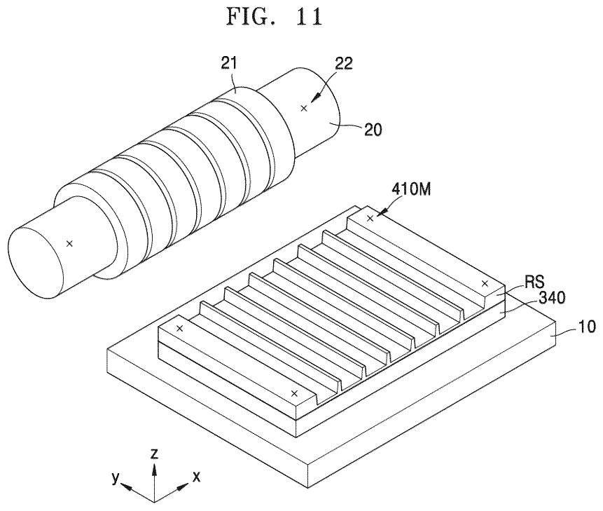

FIGS. 11 to 16 are schematic views showing a method of manufacturing the display apparatus 1 according to an embodiment.

Although a method of manufacturing a display apparatus according to an embodiment may be used to manufacture the display apparatus 1 described above, the embodiment is not limited thereto.

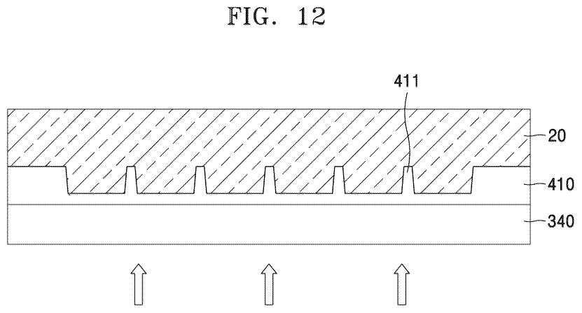

Referring to FIGS. 11 and 12, the encapsulation substrate 340 may be disposed on a stage 10. The stage 10 may support the encapsulation substrate 340 and is movable in the first direction (x direction), the second direction (y direction), and a third direction (z direction). In an embodiment, parts of the encapsulation member 300 other than the encapsulation substrate 340 may also be disposed on the stage 10.

A layer of resin RS may be disposed on the encapsulation substrate 340. The resin RS may include a material cured by an ultraviolet ray and may include a transparent material.

A pattern may be imprinted on the resin RS by a mold 20. In an embodiment, the mold 20 may be a rod extending in the first direction (x direction). The mold 20 may have protrusions 21 on an outer circumferential surface. The protrusion 21 may be formed around the outer circumferential surface of the mold 20. In an embodiment, the protrusion 21 may taper to become narrower in width with distance from the surface of the rod, measured in the radial direction. In this case, the width (measured in the first direction) of the protrusion 21 may be greater than the width W of the pixel. In other words, the protrusion 21 may protrude such that the cross-section of the protrusion 21 has a trapezoidal shape. In addition, the protrusion 21 may wrap around the outer circumferential surface of the rod to form the mold 20. That is, the protrusion 21 may be provided in a ring shape.

In an embodiment, the protrusion 21 may be provided in plurality. The plurality of protrusions 21 may be spaced apart from each other in the first direction.

In addition, in an embodiment, the mold 20 may include alignment keys 22 on two opposite sides thereof in the first direction (x direction). The alignment key 22 may protrude from the outer circumferential surface of the mold 20.

The mold 20 may imprint the resin RS by being rolled on a layer of the resin RS. In this case, ultraviolet rays may be irradiated on the resin RS to temporarily cure the resin RS. The resin RS may be imprinted with the pattern, and a portion of the resin RS that is between the protrusion 21 during the imprinting may form the body portion 411 extending in the second direction (y direction). That is, a portion of the resin RS corresponding to the protrusion 21 of the mold 20 may be imprinted, and a portion of the resin RS corresponding to the space between the protrusions 21 may form the body portion 411. In addition, it will be understood that the cross-section of the body portion 411 may be formed in the shape of a trapezoid that complements the tapered shape of the protrusion 21. In addition, the alignment mark 410M may be formed in the resin RS by the alignment key 22. The alignment mark 410M may be used to position the encapsulation substrate 340 and the light-controlling layer 400 with respect to the substrate 100 and the display layer 200 for coupling.

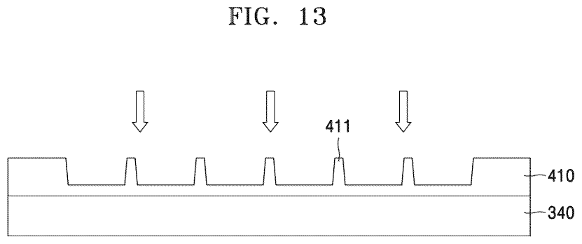

Referring to FIG. 13, the mold 20 is removed, and ultraviolet rays may be irradiated to the resin RS to cure the RS. Accordingly, the resin RS may form the transmissive layer 410, and the transmissive layer 410 may be in direct contact with the encapsulation substrate 340.

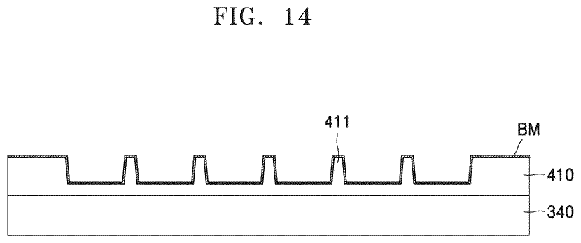

Referring to FIG. 14, a light-blocking material BM may be coated on the cured resin RS, that is, the transmissive layer 410. The light-blocking material BM may entirely cover the upper surface of the transmissive layer 410, for example, all of the body portion 411 and the spaces between the body portions 411.

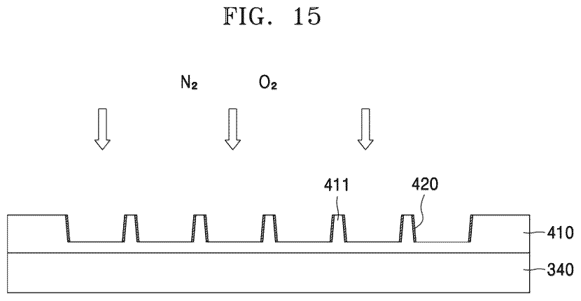

Referring to FIG. 15, a portion of the light-blocking material BM may be removed. In an embodiment, a portion of the light-blocking material BM may be removed by dry-ashing the light-blocking material BM. Nitrogen or oxygen may be used for dry ashing. Accordingly, the light-blocking material BM may remain on only the sloped second surface 411B of the body portion 411, and the light-blocking material BM may be removed from the remaining portion of the transmissive layer 410 other than the second surface 411B. The remaining light-blocking material BM may form the light-blocking coated layer 420.

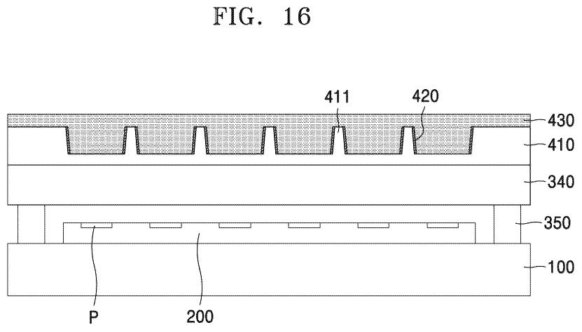

Referring to FIG. 16, the overcoat layer 430 may be disposed to cover the transmissive layer 410 and the light-blocking coated layer 420. That is, the overcoat layer 430 may be disposed to fill a space between the plurality of body portions 411, and the overcoat layer 430 may planarize the upper surface of the light-controlling layer 400.

Next, the encapsulation substrate 340 on which the light-controlling layer 400 sits may be bonded to the substrate 100 and the display layer 200 on the substrate 100. In this case, the encapsulation substrate 340 and the substrate 100 may be aligned with each other using the alignment mark 410M. In an embodiment, the positions of the encapsulation substrate 340 and the substrate 100 are captured using a camera (not shown), and the encapsulation substrate 340 and the substrate 100 may be aligned with each other using the alignment mark 410M.

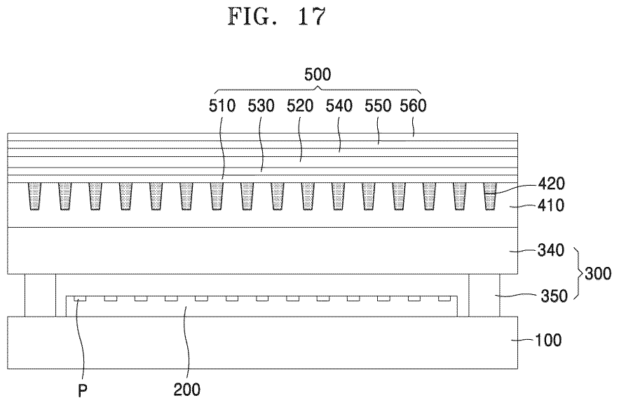

FIG. 17 is a schematic cross-sectional view of the display apparatus 1 according to another embodiment. The display apparatus 1 according to the present embodiment is similar to the display apparatus 1 described above. Hence, in the interest of avoiding redundant description, the description below will focus on the differences.

The encapsulation member 300 may be disposed on the display layer 200 to cover the display layer 200. In an embodiment, the encapsulation member 300 may include the encapsulation substrate 340 and the sealing member 350.

The light-controlling layer 400 may be disposed on the encapsulation member 300. In an embodiment, the light-controlling layer 400 may include the transmissive layer 410 and the light-blocking coated layer 420.

The transmissive layer 410 may be disposed on the encapsulation substrate 340, and in an embodiment, the transmissive layer 410 may be disposed to be in direct contact with the encapsulation substrate 340. For example, the transmissive layer 410 may be formed by being in direct contact with the encapsulation substrate 340. The transmissive layer 410 may include a transparent material. The transmissive layer 410 may include resin having a high light transmittance. For example, the transmissive layer 410 may include a cellulose resin, a polyolefin resin, a polyester resin, polystyrene, polyurethane, polyvinyl chloride, an acryl-based resin, and the like.

In an embodiment, the transmissive layer 410 may include bod portions 411 with the light-blocking coated layer 420 on the sidewalls, separated by grooves that extends in a direction (−z direction) from the polarizing film layer 500 to the encapsulation member 300.

In the embodiment of FIG. 17, the overcoat 430 is only in the grooves and does not cover the body portion 411. The groove may be provided in plurality, and the plurality of grooves may be disposed apart from each other in the first direction (x direction). In addition, each of the plurality of grooves may extend in the second direction (y direction). In an embodiment, a distance (e.g., interval in the first direction) between the plurality of grooves may be greater than the width (e.g., measured in the first direction) of a pixel. In plan view, the groove may be disposed between a plurality of pixels that are spaced apart from each other in the first direction and may extend in the second direction.

A cross-section of the groove between adjacent light-blocking coated layers 420 viewed from the second direction (y direction) may be provided in the shape of a trapezoid in an embodiment. For example, the groove may have a cross-section of a trapezoid that gets narrower with distance from the polarizing film layer 500.

The light-blocking coated layer 420 may be disposed to cover the transmissive layer 410, specifically to cover the sidewall and the base of the groove. The light-blocking coated layer 420 may be disposed to fill only the groove and may not cover the other portions of the upper surface of the transmissive layer 410. Accordingly, the light-blocking coated layer 420 may form the light-blocking line 420L. In this case, it will be understood that the light-blocking line 420L may be provided as a single line instead of a dual line.

The light-blocking lines 420L may be apart from each other and be provided in plurality, and each of the plurality of light-blocking lines 420L may extend in the second direction (y direction) crossing the first direction. In an embodiment, an interval (e.g., interval in the first direction) between the plurality of light-blocking lines 420L may be greater than the width W (e.g., distance in the first direction) of a pixel. In addition, the light-blocking lines 420L may be disposed between a plurality of pixels apart from each other in the first direction and may extend in the second direction. In other words, the plurality of light-blocking lines 420L may not overlap the plurality of pixels, and the plurality of light-blocking lines 420L may be apart from each other in the same direction as an arrangement direction of the plurality of pixels. In an embodiment, the pixels P and the light blocking lines 420L are arranged in an alternating manner along the first direction.

The light-blocking coated layer 420 may include a light-blocking material. For example, the light-blocking coated layer 420 may include black dye. The light-blocking coated layer 420 may include black ink and be formed by irradiating an ultraviolet ray. A path of light emitted from the display layer 200, for example, the pixels may be controlled according to the arrangement of the light-blocking coated layer 420.

The polarizing film layer 500 may be disposed on the transmissive layer 410. In an embodiment, the polarizing film layer 500 may include a first protective layer 510, a phase retarding layer 530, a polarizing layer 520, a second protective layer 540, and a hard coated layer 550.

The polarizing layer 520 polarizes light incident from a light source (not shown) into light in the same direction as a polarization axis. In an embodiment, the polarizing layer 520 may include at least one of a polarizer and a dichroic dye in a polyvinyl alcohol (PVA) film. Dichroic dye may be an iodine molecule, a dye molecule, or a combination of the two.

In an embodiment, the polarizing layer 520 may be formed by stretching a polyvinyl alcohol film in one direction and immersing it in a solution of iodine, a dichroic dye, or both. In this case, iodine molecules and dichroic dye molecules are arranged parallel in a stretching direction. Because iodine molecules and dye molecules exhibit dichroism, they absorb light that vibrates in the stretching direction and transmit light that vibrates in a direction perpendicular to it.

The phase retarding layer (PRL) 530 may be disposed on one side of the polarizing layer 520 and may delay the phase of light reflected by a metal layer and the like inside a display panel. As an example, the phase retarding layer 530 may circularly polarize reflected light by delaying its phase by λ/4. Accordingly, reflectivity of light may be reduced. In an embodiment, the phase retarding layer 530 may have a wavelength dependency, with a phase delay value decreasing toward shorter wavelengths. As shown in the drawing, the phase retarding layer 530 may be disposed under the polarizing layer 520.

The first protective layer 510 and the second protective layer 540 may serve as protective layers that support the polarizing layer 520 and the phase retarding layer 530 while supplementing the mechanical strength of the polarizing layer 520 and the phase regarding layer 530. The first protective layer 510 may be disposed under the phase retarding layer 530. The second protective layer 540 may be disposed on the polarizing layer 520. Alternatively, the second protective layer 540 may be disposed between the polarizing layer 520 and the phase retarding layer 530. However, various modifications m ay be made.

The first protective layer 510 and the second protective layer 540 may include triacetyl cellulose (TAC), cyclo olefin polymer, or polymethyl methacrylate (PMMA).

The hard coated layer 550 may be an element for protecting elements of the polarizing film layer 500 from external impacts. The hard coated layer 550 may have a scratch-resistant function and have a strength of about 3 H to about 9 H. Because the hard coated layer 550 is disposed over the light-controlling layer 400, not only the polarizing film layer 500 but also the light-controlling layer 400 may be protected by the hard coated layer 550.

In an embodiment, a protective film 560 may be selectively disposed on the hard coated layer 550. The protective film 560 is a temporary film for protecting the polarizing film layer 500 and may be removed afterword.

The light-controlling layer 400 may be formed by pressing and rolling the mold 20 on a layer of resin RS. In this case, the mold 20 may include protrusions 21 on an outer circumferential surface thereof. The protrusion 21 may be formed on the outer circumferential surface of the mold 20. For example, the protrusion 21 may be tapered to become narrower with distance from the surface of the mold 20. In addition, the protrusion 21 may extend along a peripheral direction of the outer circumferential surface of the mold 20. That is, the protrusion 21 may be provided in a ring shape.

In an embodiment, the protrusion 21 may be provided in plurality. The plurality of protrusions 21 may be apart from each other in the first direction. In this case, an interval between the plurality of protrusions 21 may be greater than the width of the pixel.

The mold 20 may print a pattern on the resin by being rolled on the resin. The resin is imprinted, and the imprinted portion may form the groove. That is, a portion corresponding to the protrusion 21 on the mold 20 forms the groove on the resin RS. In addition, it will be understood that the cross-section of the groove may be formed in the shape of an inverted trapezoid according to the shape of the protrusion 21.

According to an embodiment, the light-controlling layer 400 may be on the encapsulation substrate 340 and in direct contact with the encapsulation substrate 340. Accordingly, an adhesive layer for adhering the light-controlling layer 400 to the encapsulation substrate 340 may be omitted, and the manufacturing process may be simplified.

In addition, the light-controlling layer 400 may be disposed on the encapsulation substrate 340 and disposed under the polarizing film layer 500. Accordingly, a distance from the display layer 200 may be reduced compared to a case where the light-controlling layer 400 is disposed on the polarizing film layer 500. Accordingly, a transmittance of light emitted from the display layer 200 may be improved, and an issue of a double image that may occur due to a distance from the display layer 200 may be prevented.

In addition, because the light-blocking lines 420L do not overlap the pixels and are disposed between the pixels, a moire phenomenon may be prevented. The light-blocking lines 420L may be apart from each other in the same direction as the arrangement direction of the pixels and disposed in direction orthogonal to the arrangement direction, which may symmetrically implement the brightness of the display apparatus 1 compared to a case where the light-blocking lines 420L are disposed to be sloped in the arrangement direction of the pixels.

According to embodiments, because the light-controlling layer is disposed closer to the display layer than the polarizing film layer, the quality of the display apparatus may be improved.

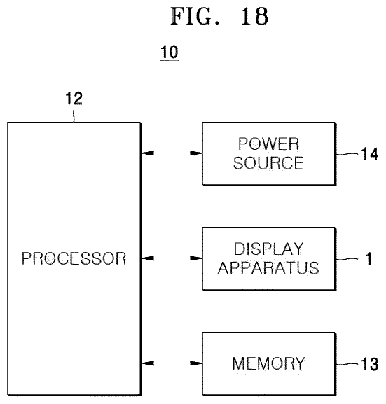

FIG. 18 is a schematic diagram of an electronic device 10 that includes the display apparatus 1 according to an embodiment. As shown, the electronic device 10 may include a processor 12, a memory 13, and a power source 14 in addition to the display apparatus 1. Data for operation of the processor 12 and/or the display apparatus 1 may be stored in the memory 15. When the processor 12 executes an application stored in the memory 15, signals (e.g., an image data signal, input control signal) is transmitted to the display apparatus 1. The display apparatus 1 may process the received signals and output an image according to the received signals. The power source 14 may be any power source including but not limited to a battery. Suitable parts available in the market may be used for the processor 12 and the memory 13, depending on the application.

Effects of the disclosure are not limited to the above mentioned effects and other effects not mentioned may be clearly understood by those of ordinary skill in the art from the claims presented herein.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus having a display area and a non-display area, comprising:
a substrate in the display area and the non-display area;
a display layer including a plurality of pixels disposed in the display area;
an encapsulation member covering the display layer;
a light-controlling layer disposed on the encapsulation member; and
a polarizing film layer disposed on the light-controlling layer,
wherein the light-controlling layer includes a plurality of light-blocking lines in a plan view, and each of the plurality of light-blocking lines includes a dual line.

2. The display apparatus of claim 1, wherein each of the plurality of light-blocking lines extends between the plurality of pixels.

3. The display apparatus of claim 1, wherein the plurality of pixels are arranged in a first direction with space between neighboring pixels, and the plurality of light-blocking lines extend in a direction that is orthogonal to the first direction.

4. The display apparatus of claim 3, wherein the plurality of light-blocking lines are disposed spaced apart from each other in the first direction.

5. The display apparatus of claim 4, wherein a separation distance between the plurality of light-blocking lines in the first direction is greater than a width of each of the pixels measured in the first direction.

6. The display apparatus of claim 1, wherein the dual line includes a pair of sub-lines, and a distance between the pair of sub-lines is less than a distance between the plurality of light-blocking lines.

7. The display apparatus of claim 1, wherein the light-controlling layer includes:
a transmissive layer disposed on the encapsulation member and including a body portion extending away from the encapsulation member;
a light-blocking coated layer covering the body portion to form the plurality of light-blocking lines; and
an overcoat layer covering the transmissive layer.

8. The display apparatus of claim 7, wherein the transmissive layer includes a transparent material.

9. The display apparatus of claim 7, wherein the transmissive layer is on the encapsulation member and in direct contact with the encapsulation member.

10. The display apparatus of claim 7, wherein the body portion has a cross-section having a shape of a trapezoid having a short side that is farther from the encapsulation member than a long side, a first surface forming the short side and second surfaces connecting an edge of the first surface to the long side on two opposite sides of the first surface.

11. The display apparatus of claim 10, wherein the light-blocking coated layer covers the second surface but not the first surface to form the dual line.

12. The display apparatus of claim 10, wherein light emitted from the display layer passes through the first surface.

13. The display apparatus of claim 7, wherein the body portion is provided in plurality, and a distance between the plurality of body portions is greater than a width of one of the pixels.

14. An electronic device including a display apparatus that has a display area and a non-display area, comprising:
a substrate in the display area and the non-display area;
a display layer including a plurality of pixels disposed in the display area;
an encapsulation member covering the display layer;
a light-controlling layer disposed on the encapsulation member; and
a polarizing film layer disposed on the light-controlling layer,
wherein the light-controlling layer includes:
a transmissive layer disposed on the encapsulation member and including body portions separated by a groove, and
a light-blocking line disposed to fill the groove.

15. The electronic device of claim 14, wherein the transmissive layer includes a transparent material.

16. The electronic device of claim 14, wherein a cross-section of each of the body portions has a trapezoidal shape.

17. The electronic device of claim 14, wherein the transmissive layer is on the encapsulation member in direct contact with the encapsulation member.

18. A method of manufacturing a display apparatus, the method comprising:
providing an encapsulation member;
disposing a layer of resin on the encapsulation member;
rolling a mold on the resin to imprint a pattern on the resin, the pattern including a plurality of body portions separated by grooves; and
disposing a light-blocking material on the imprinted resin.

19. The method of claim 18, further comprising:
ashing the light-blocking material to leave the coated light-blocking material on a sidewall of the body portion; and
removing the coated light-blocking material from a remaining portion of the body portion.

20. The method of claim 18, further comprising disposing an overcoat layer to cover the resin.
